(19) United States
(12) Patent Application Publication
(10) Pub. No.: US 2024/0274686 A1
(43) Pub. Date: Aug. 15, 2024

(54) STACKED INTEGRATED CIRCUIT DEVICE

(71) Applicant: SAMSUNG ELECTRONICS CO., LTD., Suwon-si (KR)

(72) Inventors: Byungho MOON, Suwon-si (KR); Inchan HWANG, Suwon-si (KR); Doyoung CHOI, Suwon-si (KR)

(21) Appl. No.: 18/437,473

(22) Filed: Feb. 9, 2024

(30) Foreign Application Priority Data
Feb. 13, 2023 (KR) 10-2023-0018862

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H01L 29/42392; H01L 21/823437; H01L 21/823462; H01L 27/088; H01L 29/0673; H01L 29/0847; H01L 29/66439; H01L 29/66545; H01L 29/775; H01L 29/78696

(57) ABSTRACT

A stacked integrated circuit device, including a lower active region, a lower gate pattern surrounding the lower active region, a lower dielectric layer between the lower active region and the lower gate pattern, an intermediate insulating layer on the lower active region, an upper active region on the intermediate insulating layer, an upper gate pattern surrounding the upper active region and covering the lower gate pattern, and an upper dielectric layer between the upper active region and the upper gate pattern, wherein an upper surface of the lower gate pattern is located lower in a vertical direction than an upper surface of the intermediate insulating layer, and the lower gate pattern surrounds at least a portion of a side surface of the intermediate insulating layer.

### CROSS-REFERENCE TO RELATED APPLICATION

Korean Patent Application No. 10-2023-0018862, filed on Feb. 13, 2023, in the Korean Intellectual Property Office, is incorporated by reference herein in its entirety.

### BACKGROUND

### 1. Field

A stacked integrated circuit device is disclosed.

### 2. Description of the Related Art

With the recent rapid progress of down-scaling of integrated circuit devices, it is necessary to secure not only high operating speeds but also operational accuracy for integrated circuit devices.

### SUMMARY

Embodiments are directed to a stacked integrated circuit device, including a lower active region, a lower gate pattern surrounding the lower active region, a lower dielectric layer between the lower active region and the lower gate pattern, an intermediate insulating layer on the lower active region, an upper active region on the intermediate insulating layer, an upper gate pattern surrounding the upper active region and covering the lower gate pattern, and an upper dielectric layer between the upper active region and the upper gate pattern, wherein an upper surface of the lower gate pattern is located lower in a vertical direction than an upper surface of the intermediate insulating layer, and the lower gate pattern surrounds at least a portion of a side surface of the intermediate insulating layer.

Embodiments are directed to a stacked integrated circuit device, including a lower active region including a first lower active region and a second lower active region spaced apart in a horizontal direction from the first lower active region, a lower gate pattern including a first lower gate and a second lower gate, the first lower gate surrounding the first lower active region, and the second lower gate surrounding the second lower active region, a first lower dielectric layer between the first lower active region and the first lower gate, a second lower dielectric layer between the second lower active region and the second lower gate, an intermediate insulating layer including a first intermediate insulating layer and a second intermediate insulating layer, the first intermediate insulating layer on the first lower active region, and the second intermediate insulating layer on the second lower active region, an upper active region including a first upper active region and a second upper active region, the first upper active region on the first intermediate insulating layer, and the second upper active region on the second intermediate insulating layer, an upper gate pattern surrounding the upper active region and covering the lower gate pattern, a first upper dielectric layer between the first upper active region and the upper gate pattern, and a second upper dielectric layer between the second upper active region and the upper gate pattern, wherein the lower gate pattern surrounds a portion of a side surface of the intermediate insulating layer, and the upper gate pattern surrounds a remaining portion the surface side of the intermediate insulating layer.

Embodiments are directed to a stacked integrated circuit device, including a lower active region, a lower gate pattern surrounding the lower active region, and including a protruding portion, a lower dielectric layer between the lower active region and the lower gate pattern, an intermediate insulating layer on the lower active region, an upper active region on the intermediate insulating layer, an upper gate pattern surrounding the upper active region, covering the lower gate pattern, and electrically connected to the lower gate pattern, and an upper dielectric layer between the upper active region and the upper gate pattern, wherein a threshold voltage of the upper gate pattern and a threshold voltage of the lower gate pattern are different from each other, an upper surface of the lower gate pattern is located lower in a vertical direction than an upper surface of the intermediate insulating layer, and has a downward convex shape, the lower gate pattern surrounding at least a portion of a side surface of the intermediate insulating layer, and the upper gate pattern surrounding a remaining portion of the side surface of the intermediate insulating layer.

### BRIEF DESCRIPTION OF THE DRAWINGS

Features will become apparent to those of skill in the art by describing in detail exemplary embodiments with reference to the attached drawings, in which:

FIG. 1 is a plan view showing a stacked integrated circuit device according to an example embodiment;

FIG. 2 is a cross-sectional view showing the stacked integrated circuit device taken along a line A-A′ of FIG. 1;

FIG. 3 is a cross-sectional view showing the stacked integrated circuit device taken along a line B-B′ shown in FIG. 1;

FIG. 4 is an enlarged view showing a portion IV of FIG. 3.

FIG. 5 is a cross-sectional view showing the stacked integrated circuit device taken along the line B-B′ of FIG. 1.

FIG. 6 is a cross-sectional view showing the stacked integrated circuit device taken along the line B-B′ of FIG. 1.

FIG. 7 is a cross-sectional view showing the stacked integrated circuit device taken along the line B-B′ of FIG. 1.

FIG. 8 is a cross-sectional view showing the stacked integrated circuit device taken along the line B-B′ of FIG. 1.

FIG. 9 is a cross-sectional view showing the stacked integrated circuit device taken along the line B-B′ of FIG. 1.

FIG. 10 is a plan view showing a layout of a stacked integrated circuit device.

FIG. 11 is a cross-sectional view showing a stacked integrated circuit device taken along line A-A′ of FIG. 10.

FIG. 12 is a cross-sectional view showing a stacked integrated circuit device taken along line B-B′ of FIG. 10.

FIG. 13 is a cross-sectional view showing a stacked integrated circuit device taken along line C-C′ of FIG. 10.

FIGS. 14A to 14J are cross-sectional views showing, in a process sequence, a method of manufacturing a stacked integrated circuit device.

### DETAILED DESCRIPTION

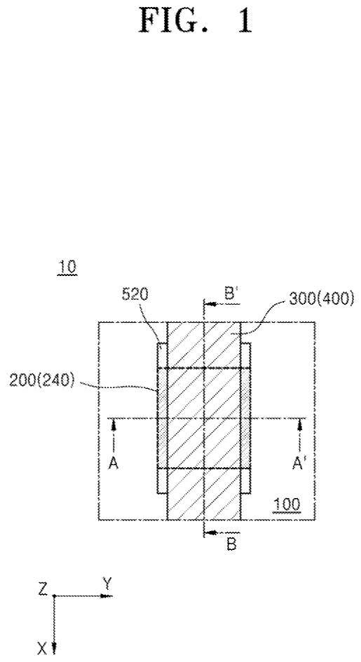

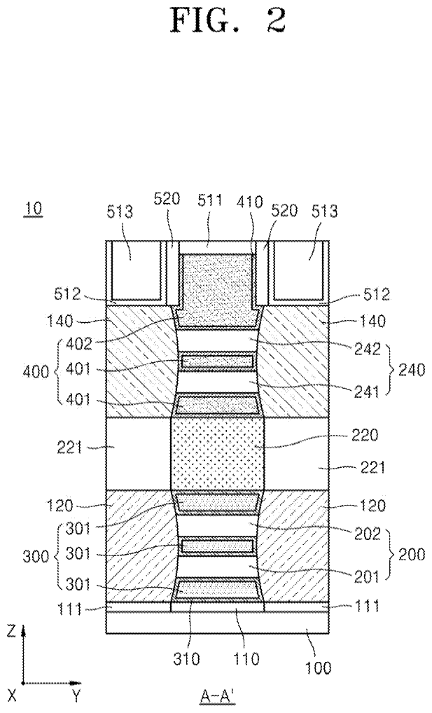

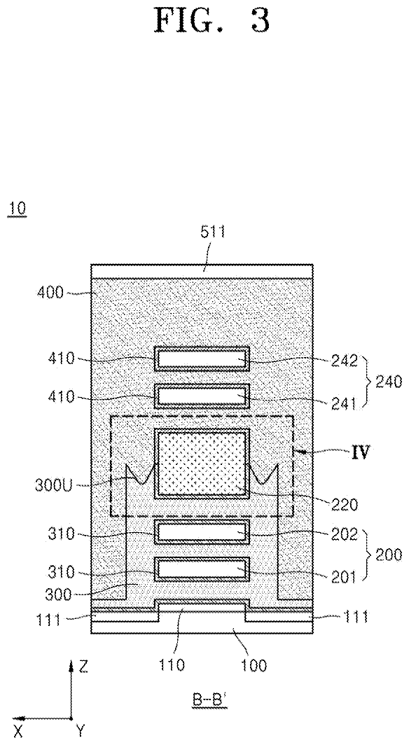

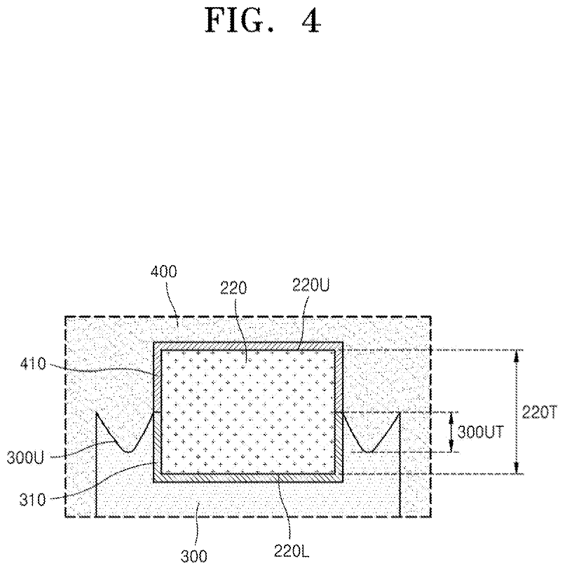

FIG. 1 is a plan view showing a stacked integrated circuit device according to an example embodiment. FIG. 2 is a cross-sectional view showing a stacked integrated circuit device taken along a line A-A′ of FIG. 1. FIG. 3 is a cross-sectional view showing the stacked integrated circuit device taken along a line B-B′ shown in FIG. 1. FIG. 4 is an enlarged view showing a portion IV of FIG. 3.

Referring to FIGS. 1 to 4, the stacked integrated circuit device 10 may include a substrate 100, a lower active region 200, a lower gate pattern 300, a lower dielectric layer 310, an intermediate insulating layer 220, an upper active region 240, an upper gate pattern 400, an upper dielectric layer 410, a lower source/drain region 120, and an upper source/drain region 140.

In the present specification, a direction in which the lower and upper gate patterns 300 and 400 extend may be an X-axis direction, and a direction horizontally perpendicular to the X-axis direction may be a Y-axis direction. A direction perpendicular to the X-axis direction and the Y-axis direction may be a Z-axis direction.

As shown in FIG. 1, in the stacked integrated circuit device 10, the upper active region 240 may overlap the lower active region 200, and the upper gate pattern 400 may overlap the lower gate pattern 300.

In other words, as shown in FIGS. 2 to 4, the stacked integrated circuit device 10 may be an integrated circuit device in which at least two layers of lower and upper active regions 200 and 240 are stacked with the intermediate insulating layer 220 therebetween. The lower and upper active regions 200 and 240 may also be referred to as channels.

The substrate 100 may include a semiconductor, such as silicon (Si) or germanium (Ge), or a compound semiconductor, such as silicon germanium {SiGe}, silicon carbide (SiC), gallium arsenide (GaAs), indium arsenide (InAs), indium gallium arsenide (InGaAs), or indium phosphide (InP). The terms “SiGe”, “SiC”, “GaAs”, “InAs”, “InGaAs”, and “InP” used in the present specification denote materials including elements included in the terms, and are not chemical formulae indicating stoichiometric relationships.

A lower insulating layer 110 and a lower oxide layer 111 may be on the substrate 100. The lower insulating layer 110 may be surrounded by the lower oxide layer 111. According to some embodiments, the substrate 100 may be removed while connecting a wire to the stacked integrated circuit device 10.

The lower active region 200 may be above the substrate 100. The lower active region 200 may be on the lower insulating layer 110. In other words, the lower active region 200 may be on the lower insulating layer 110 on the substrate 100.

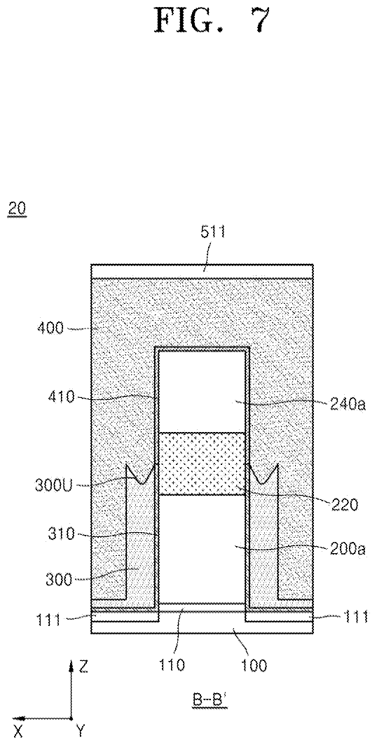

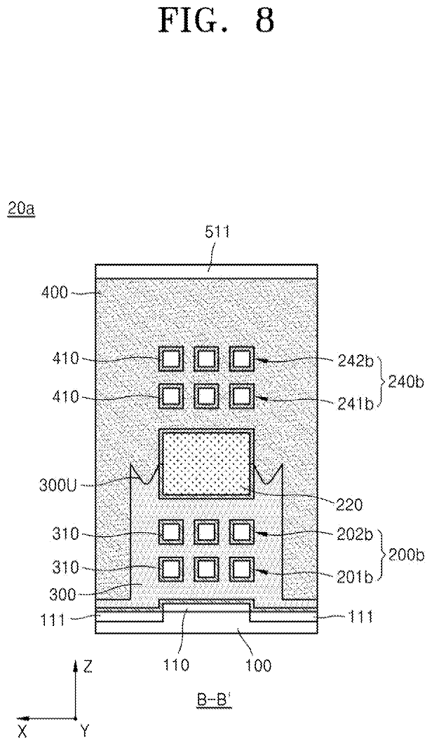

The lower active region 200 may include a fin structure, a nano-sheet, or a nano-wire. A case where the lower active region 200 includes a nano-sheet will be described with reference to FIGS. 2 to 4. Lower active regions 200a of FIGS. 7 and 200b of FIG. 8 including a fin structure and a nano-wire will be described below with reference to FIGS. 7 and 8. As used herein, the term “or” is not an exclusive term, e.g., “A or B” would include A, B, or A and B.

Referring to FIGS. 2 and 4, the lower active region 200 may include at least one lower nano-sheet. A plurality of lower nano-sheets may be spaced apart from each other in a vertical direction (the Z-axis direction). In other words, the plurality of lower nano-sheets may be spaced apart from each other in the vertical direction with a portion of the lower gate pattern 300 therebetween.

According to some embodiments, each of the plurality of lower nano-sheets may have a thickness (a length in the Z-axis direction) selected within a range from about 4 nm to about 6 nm. According to some embodiments, the plurality of lower nano-sheets may have substantially the same thickness. In other words, a first lower nano-sheet 201 and a second lower nano-sheet 202 may have substantially the same thickness.

According to some embodiments, at least some of the plurality of lower nano-sheets may have different thicknesses from the other lower nano-sheets. In other words, the first lower nano-sheet 201 and the second lower nano-sheet 202 may have different thicknesses.

According to some embodiments, the plurality of lower nano-sheets may have substantially the same length (a length in the X-axis direction) and the same width (a length in the Y-axis direction). According to some embodiments, at least some of the plurality of lower nano-sheets may have different lengths and/or widths from the other lower nano-sheets.

According to some embodiments, the lengths and/or widths of the plurality of lower nano-sheets may decrease as the plurality of lower nano-sheets are spaced apart from the substrate 100. According to some embodiments, if the plurality of lower nano-sheets are cut in an XZ plane, a cross section thereof may have a trapezoid shape.

According to some embodiments, the plurality of lower nano-sheets may be spaced apart from each other by about 7 nm to about 13 nm. In other words, a distance between an upper surface of the first lower nano-sheet 201 and a lower surface of the second lower nano-sheet 202 may be about 7 nm to about 13 nm. In FIGS. 2 to 4, the lower active region 200 includes two nano-sheets, and the lower active region 200 may include three or more nano-sheets.

The intermediate insulating layer 220 may be on the lower active region 200. The intermediate insulating layer 220 may insulate the upper active region 240 described below from the lower active region 200. In other words, the intermediate insulating layer 220 may be between the upper active region 240 and the lower active region 200. According to some embodiments, the lower active region 200 may be located below the intermediate insulating layer 220 and the upper active region 240 may be located above the intermediate insulating layer 220.

According to some embodiments, the intermediate insulating layer 220 may have substantially the same length and width as the lower nano-sheet. Alternatively, the intermediate insulating layer 220 may have a greater width than the lower nano-sheet.

According to some embodiments, a length from an upper surface 220U to a lower surface 220L of the intermediate insulating layer 220, i.e., a thickness 220T of the intermediate insulating layer 220, may be from 20 nm to 50 nm. The thickness 220T of the intermediate insulating layer 220 may be greater than the thickness of each of the plurality of lower nano-sheet.

According to some embodiments, the intermediate insulating layer 220 may include silicon nitride (SiN), silicon oxide (SiO), silicon carbon nitride (SiCN), silicon boron nitride (SiBN), SiON, SiOCN, SiBCN, or SiOC. The upper active region 240 may be on the intermediate insulating layer 220. The upper active region 240 may overlap the lower active region 200 with the intermediate insulating layer 220 therebetween.

The upper active region 240 may include a fin structure, a nano-sheet, or a nano-wire. A case where the upper active region 240 includes a nano-sheet will be described with reference to FIGS. 2 to 4. Upper active regions 240a of FIGS. 7 and 240b of FIG. 8 including a fin structure and a nano-wire will be described below with reference to FIGS. 7 and 8.

Referring to FIGS. 2 to 4, the upper active region 240 may include at least one upper nano-sheet. A plurality of upper nano-sheets may be spaced apart from each other in the vertical direction (the Z-axis direction). In other words, the plurality of upper nano-sheets may be spaced apart from each other in the vertical direction with a portion of the upper gate pattern 400 therebetween.

According to some embodiments, each of the plurality of upper nano-sheets may have a thickness selected within a range from about 4 nm to about 6 nm. According to some embodiments, the plurality of upper nano-sheets may have substantially the same thickness. According to some embodiments, at least some of the plurality of upper nano-sheets may have different thicknesses from the other upper nano-sheets.

According to some embodiments, the plurality of upper nano-sheets may have substantially the same thickness and same width. According to some embodiments, at least some of the plurality of upper nano-sheets may have different lengths and/or widths from the other upper nano-sheets.

According to some embodiments, the lengths and/or widths of the plurality of upper nano-sheets may decrease as the plurality of upper nano-sheets are spaced apart from the substrate 100. According to some embodiments, if the plurality of upper nano-sheets are cut in an XZ plane, a cross section thereof may have a trapezoid shape.

A size of the stacked integrated circuit device 10 may be reduced by locating the upper active region 240 above the lower active region 200. In other words, the pluralities of lower and upper active regions 200 and 240 may be stacked in the vertical direction so as to arrange a relatively large number of lower and upper active regions 200 and 240 in a fixed area of the substrate 100. The lower gate pattern 300 may surround the lower active region 200. In other words, the lower active region 200 may be surrounded by the lower gate pattern 300.

According to some embodiments, if the lower active region 200 includes the plurality of lower nano-sheets as shown in FIGS. 2 to 4, the lower gate pattern 300 may surround all surfaces of the lower active region 200.

The lower gate pattern 300 may cover the lower active region 200. In other words, each of the plurality of lower nano-sheets may be surrounded. The lower gate pattern 300 may include a plurality of sub-gate portions 301. The plurality of sub-gate portions 301 may be respectively between the plurality of lower nano-sheets, and one sub-gate portion 301 may be between the first lower nano-sheet 201 and the lower insulating layer 110.

The upper gate pattern 400 may surround the upper active region 240 and cover the lower gate pattern 300. In other words, the upper gate pattern 400 may cover both an upper surface 300U and side surface of the lower gate pattern 300. According to some embodiments, the upper gate pattern 400 may be in contact with the upper surface 300U and side surface of the lower gate pattern 300.

If the upper active region 240 includes the plurality of upper nano-sheets, the upper gate pattern 400 may surround each of the plurality of upper nano-sheets. The upper gate pattern 400 may include a main gate portion 402 and a plurality of sub-gate portions 401. The main gate portion 402 may extend in the X-axis direction while covering an upper surface of a second upper nano-sheet 242. The plurality of sub-gate portions 401 may be integrally connected to the main gate portion 402, respectively between the plurality of upper nano-sheets, and between a first upper nano-sheet 241 and the intermediate insulating layer 220. A thickness of each of the plurality of sub-gate portions 401 in the vertical direction (Z-axis direction) may be less than a thickness of the main gate portion 402.

The lower gate pattern 300 and the upper gate pattern 400 may include a metal, a metal nitride, or a metal carbide. The metal may be titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), or palladium (Pd). The metal nitride may be titanium nitride (TiN), titanium aluminum nitride (TiAlN), or tantalum nitride (TaN). The metal carbide may be titanium aluminum carbide (TiAlC).

According to some embodiments, a work function of the upper gate pattern 400 and a work function of the lower gate pattern 300 may be different from each other. In other words, the materials included in the upper gate pattern 400 and the lower gate pattern 300 may be adjusted such that a dopant with which the upper source/drain region 140 on both sides of the upper gate pattern 400 may be doped, and a dopant with which the lower source/drain region 120 on both sides of the lower gate pattern 300 is doped are different from each other, and thus the upper gate pattern 400 and the lower gate pattern 300 have work functions according to the dopants.

In an implementation, the work function of the upper gate pattern 400 may be greater than the work function of the lower gate pattern 300. In other words, the work function of the upper gate pattern 400 may be about 5 eV and the work function of the lower gate pattern 300 may be about 4.2 eV. Alternatively, the work function of the upper gate pattern 400 may be less than the work function of the lower gate pattern 300.

According to some embodiments, the lower gate pattern 300 and the upper gate pattern 400 may be in contact with each other. The upper gate pattern 400 may be in contact with the upper surface 300U and side surface of the lower gate pattern 300. A lower surface of the upper gate pattern 400 may correspond to shapes of the upper surface 300U and side surface of the lower gate pattern 300. The upper gate pattern 400 and the lower gate pattern 300 may be in contact with each other and thus the upper gate pattern 400 and the lower gate pattern 300 may be electrically connected to each other.

Shapes of the lower gate pattern 300 and upper gate pattern 400 will be described in detail below with reference to FIG. 4. The lower dielectric layer 310 may be between the lower active region 200 and the lower gate pattern 300. The lower dielectric layer 310 may be on a surface of the lower active region 200 and at least a portion of a surface of the lower source/drain region 120, such that the lower gate pattern 300 may not be in direct contact with the lower active region 200 and the lower source/drain region 120.

According to some embodiments, the lower dielectric layer 310 may cover the lower insulating layer 110 and at least a portion of an upper surface of the lower oxide layer 111. According to some embodiments, the lower dielectric layer 310 may cover a portion of the intermediate insulating layer 220.

The upper dielectric layer 410 may be between the upper active region 240 and the upper gate pattern 400. The upper dielectric layer 410 may be on a surface of the upper active region 240 and at least a portion of a surface of the upper source/drain region 140, such that the upper gate pattern 400 may not be in direct contact with the upper active region 240 and the upper source/drain region 140. According to some embodiments, the upper dielectric layer 410 may cover a portion of the intermediate insulating layer 220.

According to some embodiments, the lower dielectric layer 310 and the upper dielectric layer 410 may each have a stack structure of an interface layer and a high-dielectric layer. The interface layer may include a low-dielectric material layer having a dielectric constant equal to or less than about 7, and e.g., may include a silicon oxide layer, or a silicon oxynitride layer. According to some embodiments, the interface layer may be omitted. According to some embodiments, the interface layer and the high-dielectric layer may be fused through an annealing process.

The high-dielectric layer may include a material having a higher dielectric constant than a silicon oxide layer. In an implementation, the high-dielectric layer may have a dielectric constant between about 7 to about 25. According to some embodiments, the high-dielectric layer may include a metal oxide material or metal silicate having a dielectric constant greater than 7, such as Hf, aluminum (Al), zirconium (Zr), lanthanum (La), magnesium (Mg), barium (Ba), Ti, or lead (Pb).

According to some embodiments, the dielectric constants of the lower dielectric layer 310 and upper dielectric layer 410 may be the same. The dielectric constant of the lower dielectric layer 310 and the dielectric constant of the upper dielectric layer 410 may be different from each other A threshold voltage of the upper gate pattern 400 may vary depending on the dielectric constant of the upper dielectric layer 410. A threshold voltage of the lower gate pattern 300 may vary depending on the dielectric constant of the lower dielectric layer 310.

According to some embodiments, the lower dielectric layer 310 may cover a portion of the intermediate insulating layer 220 and the upper dielectric layer 410 may cover a remaining portion of the intermediate insulating layer 220. In other words, when viewed vertically, the lower dielectric layer 310 may cover the intermediate insulating layer 220 by a certain height, and the upper dielectric layer 410 may cover the remaining portion of the intermediate insulating layer 220.

While forming the upper dielectric layer 410, the lower dielectric layer 310 may be removed with a process margin, with the intermediate insulating layer 220 as a criterion for stopping removal of the lower dielectric layer 310. Then, the upper dielectric layer 410 may be on a surface of the intermediate insulating layer 220, from which the lower dielectric layer 310 may be removed.

A pair of the lower source/drain regions 120 may be respectively on both sides of the lower gate pattern 300. In other words, the pair of lower source/drain regions 120 may be spaced apart from each other with the lower gate pattern 300 and lower active region 200 therebetween. The pair of lower source/drain regions 120 may be located on both sides of the lower gate pattern 300 by being spaced apart from each other in the Y-axis direction.

The lower active region 200 may have a surface in contact with the lower source/drain region 120. In other words, at least a portion of the lower active region 200 may be in contact with the lower source/drain region 120, and thus the lower active region 200 may provide a moving path of electrons.

A pair of the upper source/drain regions 140 may be respectively on both sides of the upper gate pattern 400. In other words, the pair of upper source/drain regions 140 may be spaced apart from each other with the upper gate pattern 400 and upper active region 240 therebetween. The pair of upper source/drain regions 140 may be located on both sides of the upper gate pattern 400 by being spaced apart from each other in the Y-axis direction.

The upper active region 240 may have a surface in contact with the upper source/drain region 140. In other words, at least a portion of the upper active region 240 may be in contact with the upper source/drain region 140, and thus the upper active region 240 may provide a moving path of electrons.

A first insulating layer 221 may be located between the upper source/drain region 140 and the lower source/drain region 120. The first insulating layer 221 may be on both sides of the intermediate insulating layer 220. The first insulating layer 221 may prevent a phenomenon in which a current flows between the upper source/drain region 140 and the lower source/drain region 120.

According to some embodiments, the lower source/drain region 120 and the upper source/drain region 140 may include an epitaxially-grown semiconductor layer. According to some embodiments, the lower source/drain region 120 and the upper source/drain region 140 may include a IV-group element semiconductor, or a IV-IV-group compound semiconductor.

According to some embodiments, the lower source/drain region 120 and the upper source/drain region 140 may each include an n-type dopant doped Si layer, an n-type dopant doped SiC layer, or a p-type dopant doped SiGe layer. The n-type dopant may be phosphorous (P), arsenic (As), or antimony (Sb). The p-type dopant may be boron (B) or gallium (Ga).

A type of dopant with which the upper source/drain region 140 is doped and a type of dopant with which the lower source/drain region 120 is doped may be different from each other. In other words, the upper source/drain region 140 may be doped with one dopant among the p-type dopant and the n-type dopant, and the lower source/drain region 120 may be doped with the other dopant. In an implementation, if the upper source/drain region 140 is doped with the p-type dopant, the lower source/drain region 120 may be doped with the n-type dopant.

A plurality of insulating spacers 520 may cover both side walls of the upper gate pattern 400. According to some embodiments, the plurality of insulating spacers 520 may cover both side walls of the main gate portion 402 of the upper gate pattern 400, from an upper surface of the first upper nano-sheet 241. The plurality of insulating spacers 520 may each be spaced apart from the upper gate pattern 400 with the upper dielectric layer 410 therebetween.

The upper source/drain region 140 and the plurality of insulating spacers 520 may each be covered by an insulating liner 512. The insulating liner 512 may include SiN, SiO, SiCN, SiBN, SiON, SiOCN, SiBCN, or SiOC. According to some embodiments, the insulating liner 512 may be omitted.

An inter-gate insulating layer 513 may be on the insulating liner 512. The inter-gate insulating layer 513 may include a silicon nitride layer, a silicon oxide layer, SiON, or SiOCN. If the insulating liner 512 is omitted, the inter-gate insulating layer 513 may be in contact with the upper source/drain region 140 and the plurality of insulating spacers 520.

A capping layer 511 may be on each upper gate pattern 400. According to some embodiments, the capping layer 511 may be on an upper surface of the upper gate pattern 400, an upper surface of the insulating liner 512, and upper surfaces of the plurality of insulating spacers 520. A lower surface of the capping layer 511 may be convex towards an upper surface of the substrate 100, and an upper surface of the capping layer 511 may be parallel to the upper surface of the substrate 100. The capping layer 511 may include an insulating material (e.g., a silicon nitride layer or a silicon oxynitride layer).

Hereinafter, a shape of the lower gate pattern 300 will be described in detail with reference to FIGS. 3 and 4. The upper surface 300U of the lower gate pattern 300 may be located lower than a lower surface of the upper active region 240. In other words, a distance from the substrate 100 to the upper surface 300U of the lower gate pattern 300 may be less than a distance from the substrate 100 to the lower surface of the upper active region 240. The upper surface 300U of the lower gate pattern 300 may be located lower than the upper surface 220U of the intermediate insulating layer 220.

A highest point of the upper surface 300U of the lower gate pattern 300 may be located higher than the lower active region 200. In other words, the highest point of the upper surface 300U of the lower gate pattern 300 may be located lower than the upper active region 240 and higher than the lower active region 200.

According to some embodiments, the upper surface 300U of the lower gate pattern 300 may be located between the upper surface 220U of the intermediate insulating layer 220 and the lower surface 220L of the intermediate insulating layer 220. A lowest point of the upper surface 300U of the lower gate pattern 300 may be located lower than the lower surface 220L of the intermediate insulating layer 220, and the highest point of the upper surface 300U of the lower gate pattern 300 may be located at a same height as the upper surface 220U of the intermediate insulating layer 220.

In FIGS. 3 and 4, the lower gate pattern 300 surrounds the lower dielectric layer 310 formed in the intermediate insulating layer 220, and the lower gate pattern 300 may surround the lower dielectric layer 310 and upper dielectric layer 410 formed in the intermediate insulating layer 220 according to an etching degree of the lower gate pattern 300. In other words, a criterion for stopping an etching process of the lower gate pattern 300 may be independent from the upper dielectric layer 410 and lower dielectric layer 310 formed in the intermediate insulating layer 220.

The lower gate pattern 300 may be in contact with a portion of the intermediate insulating layer 220 and the upper gate pattern 400 may be in contact with a remaining portion of the intermediate insulating layer 220. In other words, the upper gate pattern 400 may cover the lower gate pattern 300, and thus a portion of the intermediate insulating layer 220, which may not be in contact with the lower gate pattern 300, may be in contact with the upper gate pattern 400. The lower gate pattern 300 may surround the intermediate insulating layer 220 below a certain height on a side surface of the intermediate insulating layer 220, and the upper gate pattern 400 may surround the intermediate insulating layer 220 above a certain height on the side surface of the intermediate insulating layer 220. A region of the intermediate insulating layer 220 surrounded by the upper gate pattern 400 may vary depending on a degree the lower gate pattern 300 is etched.

After the lower gate pattern 300 covers the upper active region 240, the upper surface 300U of the lower gate pattern 300 may be recessed lower than the upper surface 220U of the intermediate insulating layer 220 during a process of partially recessing the lower gate pattern 300 to externally expose the upper active region 240.

According to some embodiments, the upper surface 300U of the lower gate pattern 300 may be convex downward. In other words, a height of the lower gate pattern 300 may decrease towards a center of the upper surface 300U of the lower gate pattern 300. In other words, the lower gate pattern 300 may have an inward convex shape from the upper surface 300U of the lower gate pattern 300, on a cross section of the lower gate pattern 300 cut in an XZ plane.

A distance from the substrate 100 may increase as the upper surface 300U of the lower gate pattern 300 approaches a side wall of the lower gate pattern 300. In other words, the highest point of the upper surface 300U of the lower gate pattern 300 may be located at a corner of the upper surface 300U of the lower gate pattern 300, and the lowest point of the upper surface 300U of the lower gate pattern 300 may be located at a center of the upper surface 300U of the lower gate pattern 300. Here, the highest point may be a point of the upper surface 300U of the lower gate pattern 300, where a vertical distance to the substrate 100 is the largest, and the lowest point may be a point of the upper surface 300U of the lower gate pattern 300, where the vertical distance to the substrate 100 is the smallest.

According to some embodiments, a difference 300UT between a height from the substrate 100 to the highest point of the upper surface 300U of the lower gate pattern 300 and a height from the substrate 100 to the lowest point of the upper surface 300U of the lower gate pattern 300 may be 1 nm to 10 nm. In other words, the difference 300UT of height in the upper surface 300U of the lower gate pattern 300 may be 1 nm to 10 nm.

The upper gate pattern 400 may be located on the downward convex upper surface 300U of the lower gate pattern 300. In other words, the upper gate pattern 400 may be located while in contact with the downward convex upper surface 300U of the lower gate pattern 300. In other words, the lower surface of the upper gate pattern 400 and the upper surface 300U of the lower gate pattern 300 may correspond to each other.

A shape of the upper surface 300U of the lower gate pattern 300 may be determined while recessing a portion of the lower gate pattern 300. In other words, if a recess of the lower gate pattern 300 is formed through a wet-etching process, the lower gate pattern 300 may be isotropically etched, and thus the upper surface 300U may have a downward convex shape. In other words, while recessing the lower gate pattern 300, both sides of the lower gate pattern 300 are in contact with different materials, and thus an etching speed thereof may be less than an etching speed of the center of the upper surface 300U of the lower gate pattern 300. Accordingly, the center of the upper surface 300U of the lower gate pattern 300, which has a greater etching speed, may be etched relatively a lot, and thus the upper surface 300U of the lower gate pattern 300 may have a downward convex shape.

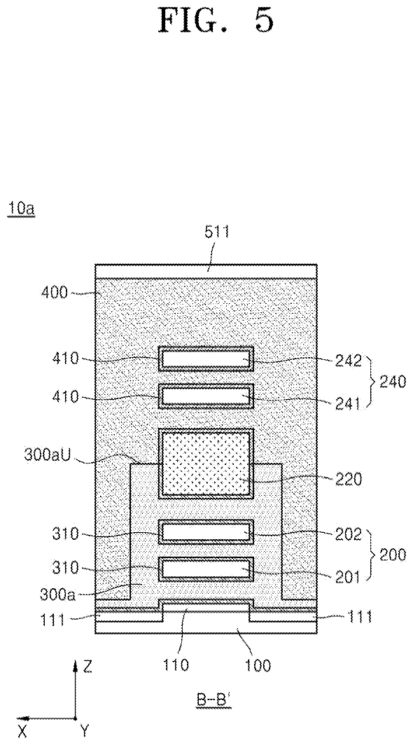

FIG. 5 is a cross-sectional view showing a stacked integrated circuit device taken along the line B-B′ of FIG. 1. The stacked integrated circuit device 10a shown in FIG. 5 may be substantially identical to the stacked integrated circuit device 10 of FIG. 3, except for a shape of a lower gate pattern 300a.

Hereinafter, details of the stacked integrated circuit device 10a of FIG. 5, which overlap the stacked integrated circuit device 10 of FIG. 3 are omitted, and differences will be described. The lower gate pattern 300a may surround the lower active region 200. In other words, the lower active region 200 may be surrounded by the lower gate pattern 300a.

The lower gate pattern 300a may surround the lower surface and at least a portion of the side surface of the intermediate insulating layer 220. In other words, the lower gate pattern 300a may extend to below the upper surface of the intermediate insulating layer 220, on the substrate 100. The lower active region 200 and at least a portion of the intermediate insulating layer 220 may be located inside the lower gate pattern 300a.

An upper surface 300aU of the lower gate pattern 300a may be parallel to the upper surface of the substrate 100. In other words, the upper surface 300aU of the lower gate pattern 300a and the upper surface of the substrate 100 may be parallel to each other. In other words, the upper surface 300aU of the lower gate pattern 300a may be flat without a curve.

According to some embodiments, the lower gate pattern 300a may be recessed through dry etching. In other words, a portion of the lower gate pattern 300a may be removed through anisotropic etching. If the portion of the lower gate pattern 300a may be recessed through an etching process having directivity, the upper surface 300aU of the lower gate pattern 300a may be flat.

The upper gate pattern 400 may be in contact with the upper surface 300aU and side surface of the lower gate pattern 300a. In other words, the upper gate pattern 400 may fill a space in an upper portion of the lower gate pattern 300a. If the upper surface 300aU of the lower gate pattern 300a is flat, a portion of the lower surface of the upper gate pattern 400, which faces the upper surface 300aU of the lower gate pattern 300a, may be parallel to the substrate 100. In other words, a shape of the lower surface of the upper gate pattern 400 and a shape of the upper surface 300aU of the lower gate pattern 300a may correspond to each other.

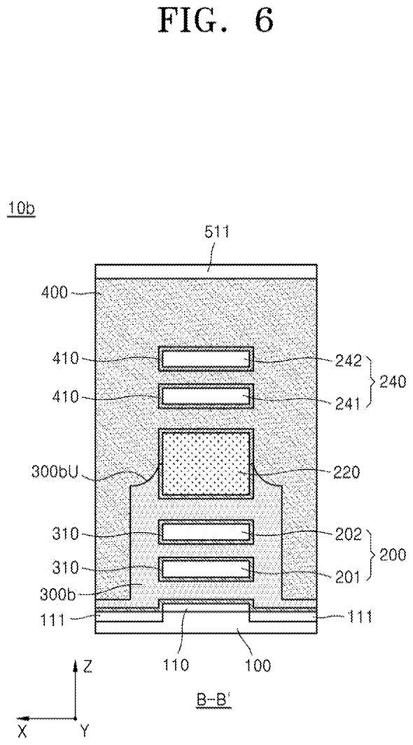

FIG. 6 is a cross-sectional view showing a stacked integrated circuit device taken along the line B-B′ of FIG. 1. The stacked integrated circuit device 10b shown in FIG. 6 may be substantially identical to the stacked integrated circuit device 10 of FIG. 3, except for a shape of a lower gate pattern 300b.

Hereinafter, details of the stacked integrated circuit device 10b of FIG. 6, which overlap the stacked integrated circuit device 10 of FIG. 3 are omitted, and differences will be described.

The lower gate pattern 300b may surround the lower active region 200. In other words, the lower active region 200 may be surrounded by the lower gate pattern 300b.

The lower gate pattern 300b may surround the lower surface and at least a portion of the side surface of the intermediate insulating layer 220. In other words, the lower gate pattern 300b may extend to below the upper surface of the intermediate insulating layer 220, on the substrate 100. The lower active region 200 and at least a portion of the intermediate insulating layer 220 may be located inside the lower gate pattern 300b.

An upper surface 300bU of the lower gate pattern 300b may approach the substrate 100 while being spaced apart from the intermediate insulating layer 220. In other words, a distance from the substrate 100 to the upper surface 300bU of the lower gate pattern 300b, i.e., a height of the lower gate pattern 300b, may decrease towards the side surface of the lower gate pattern 300b.

While dry etching is performed on a portion of the lower gate pattern 300b, an etching speed may vary according to regions of the lower gate pattern 300b. In other words, the etching speed may be low in a region of the lower gate pattern 300b close to the intermediate insulating layer 220, and thus the lower gate pattern 300b may be etched such that the upper surface 300bU of the lower gate pattern 300b is inclined.

In other words, the upper surface 300bU of the lower gate pattern 300b may be inclined based on the upper surface of the substrate 100, in a cross section of the lower gate pattern 300b cut in the XZ plane. In FIG. 6, the upper surface 300bU of the lower gate pattern 300b approaches the substrate 100 while forming a curve when viewed from the cross section of the lower gate pattern 300b cut in the XZ plane, and the upper surface 300bU of the lower gate pattern 300b may approach the substrate 100 while forming a straight line.

The upper gate pattern 400 may be in contact with the upper surface 300bU and side surface of the lower gate pattern 300b. In other words, the upper gate pattern 400 may fill a space in an upper portion of the lower gate pattern 300b.

FIG. 7 is a cross-sectional view showing a stacked integrated circuit device taken along the line B-B′ of FIG. 1. The stacked integrated circuit device 20 shown in FIG. 7 may be substantially identical to the stacked integrated circuit device 10 of FIG. 3, except for the upper active region 240a and the lower active region 200a.

Hereinafter, details of the stacked integrated circuit device 20 of FIG. 7, which overlap the stacked integrated circuit device 10 of FIG. 3 are omitted, and differences will be described.

The upper active region 240a may include a fin structure. The upper active region 240a may include a fin structure extending in the X-axis direction. The upper active region 240a may protrude upward on the intermediate insulating layer 220 and extend in the Z-axis direction. The upper dielectric layer 410 may be on a side surface and upper surface of the fin structure of the upper active region 240a, and a lower surface thereof may be in contact with the intermediate insulating layer 220. In other words, a transistor including the upper active region 240a, the upper gate pattern 400, and the upper source/drain region 140 of FIG. 2 may have a fin field-effect transistor (FET) structure.

The lower active region 200a may include a fin structure. The lower active region 200a may include a fin structure extending in the X-axis direction. The lower active region 200a may protrude upward on the lower insulating layer 110 and extend in the Z-axis direction. The lower dielectric layer 310 may be on a side surface of the fin structure of the lower active region 200a, a lower surface thereof may be in contact with the lower insulating layer 110, and an upper surface thereof may be in contact with the intermediate insulating layer 220. In other words, a transistor including the lower active region 200a, the lower gate pattern 300, and the lower source/drain region 120 of FIG. 2 may have a fin FET structure.

FIG. 8 is a cross-sectional view showing a stacked integrated circuit device taken along the line B-B′ of FIG. 1. The stacked integrated circuit device 20a shown in FIG. 8 may be substantially identical to the stacked integrated circuit device 10 of FIG. 3, except for the upper active region 240b and the lower active region 200b.

Hereinafter, details of the stacked integrated circuit device 20a of FIG. 8, which overlap the stacked integrated circuit device 10 of FIG. 3 are omitted, and differences will be described.

The upper active region 240b and the lower active region 200b may include a plurality of nano-wires. The upper active region 240b and the lower active region 200b may include the plurality of nano-wires that have substantially the same length (a length in the X-axis direction) and the same thickness (a length in the Z-axis direction). In other words, a cross section of the nano-wire cut in the XZ plane may be a square. According to some embodiments, a length and thickness of the nano-wire may be in a range from about 4 nm to about 6 nm.

The upper active region 240b may include a first upper nano-wire layer 241b and a second upper nano-wire layer 242b, which are spaced apart from each other in the Z-axis direction. According to some embodiments, a distance between the first upper nano-wire layer 241b and the second upper nano-wire layer 242b in the Z-axis direction may be about 7 nm to about 13 nm. In FIG. 8, the plurality of nano-wires are stacked in two layers.

The plurality of nano-wires may be spaced apart from each other in the X-axis direction in the first upper nano-wire layer 241b. According to some embodiments, a distance between the nano-wires in the X-axis direction may be about 7 nm to about 13 nm. In FIG. 8, three nano-wires are arranged in the first upper nano-wire layer 241b. The second upper nano-wire layer 242b may be substantially the same as the first upper nano-wire layer 241b.

The upper dielectric layer 410 may be between the plurality of nano-wires of the upper active region 240b and the upper gate pattern 400. In other words, each of the plurality of nano-wires may be surrounded by the upper gate pattern 400 with the upper dielectric layer 410 therebetween.

The lower active region 200b may include a first lower nano-wire layer 201b and a second lower nano-wire layer 202b, which are spaced apart from each other in the Z-axis direction. According to some embodiments, a distance between the first lower nano-wire layer 201b and the second lower nano-wire layer 202b in the Z-axis direction may be about 7 nm to about 13 nm. In FIG. 8, the plurality of nano-wires are stacked in two layers.

The plurality of nano-wires may be spaced apart from each other in the X-axis direction in the first lower nano-wire layer 201b. According to some embodiments, a distance between the nano-wires in the X-axis direction may be about 7 nm to about 13 nm. In FIG. 8, three nano-wires are arranged in the first lower nano-wire layer 201b. The second lower nano-wire layer 202b may be substantially the same as the first lower nano-wire layer 201b.

The lower dielectric layer 310 may be between the plurality of nano-wires of the lower active region 200b and the lower gate pattern 300. In other words, each of the plurality of nano-wires may be surrounded by the lower gate pattern 300 with the lower dielectric layer 310 therebetween.

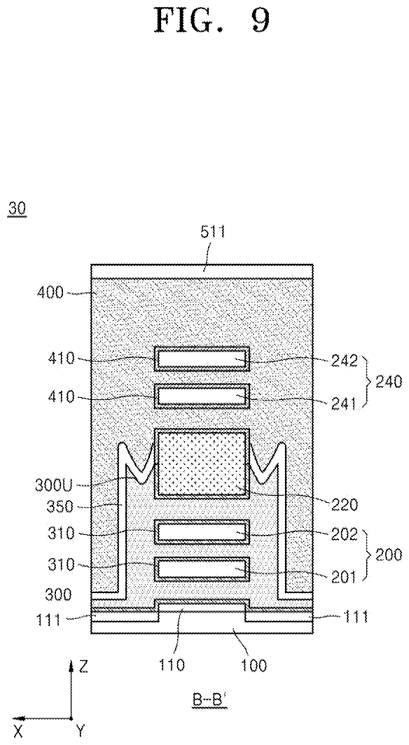

FIG. 9 is a cross-sectional view showing a stacked integrated circuit device taken along the line B-B′ of FIG. 1. Referring to FIG. 9, the stacked integrated circuit device 30 may include the substrate 100, the lower active region 200, the lower gate pattern 300, the lower dielectric layer 310, the intermediate insulating layer 220, a gate insulating layer 350, the upper active region 240, the upper gate pattern 400, the upper dielectric layer 410, the lower source/drain region 120 of FIG. 2, and the upper source/drain region 140 of FIG. 2.

Hereinafter, details of the stacked integrated circuit device 30 of FIG. 9, which overlap the stacked integrated circuit device 10 of FIG. 3 are omitted, and differences will be described.

The gate insulating layer 350 may be between the lower gate pattern 300 and the upper gate pattern 400. In other words, the lower gate pattern 300 and the upper gate pattern 400 may be spaced apart from each other with the gate insulating layer 350 therebetween. The gate insulating layer 350 may prevent a current from flowing between the lower gate pattern 300 and the upper gate pattern 400.

The gate insulating layer 350 may be conformally formed on a surface of the lower gate pattern 300. In other words, after the lower gate pattern 300 is formed, the gate insulating layer 350 may be formed on the surface of the lower gate pattern 300 to have a uniform thickness.

In other words, a shape of the gate insulating layer 350 may correspond to a shape of the lower gate pattern 300. In other words, a portion of the gate insulating layer 350 on the upper surface 300U of the lower gate pattern 300 may be curved or flat according to the shape of the upper surface 300U of the lower gate pattern 300.

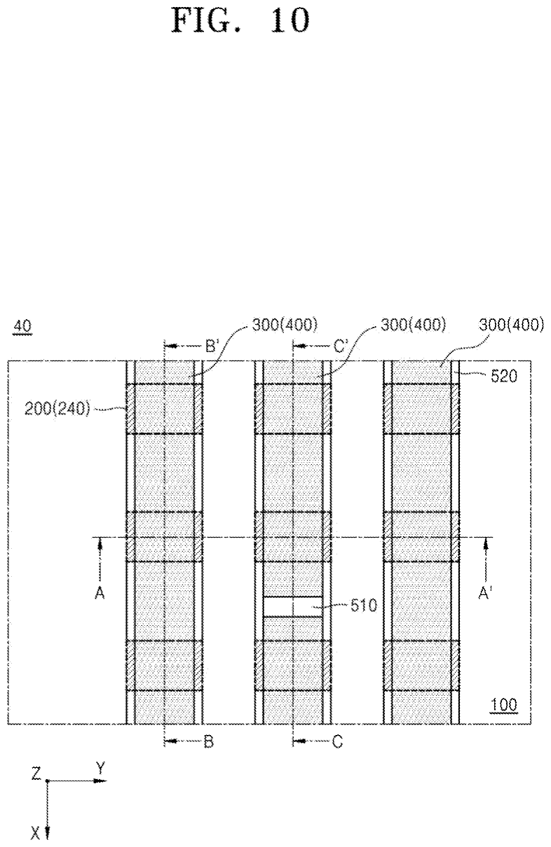

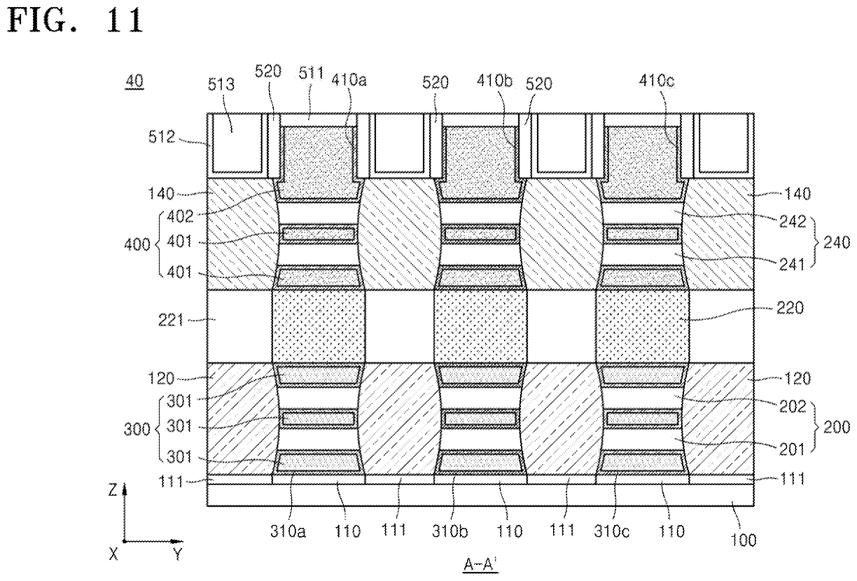

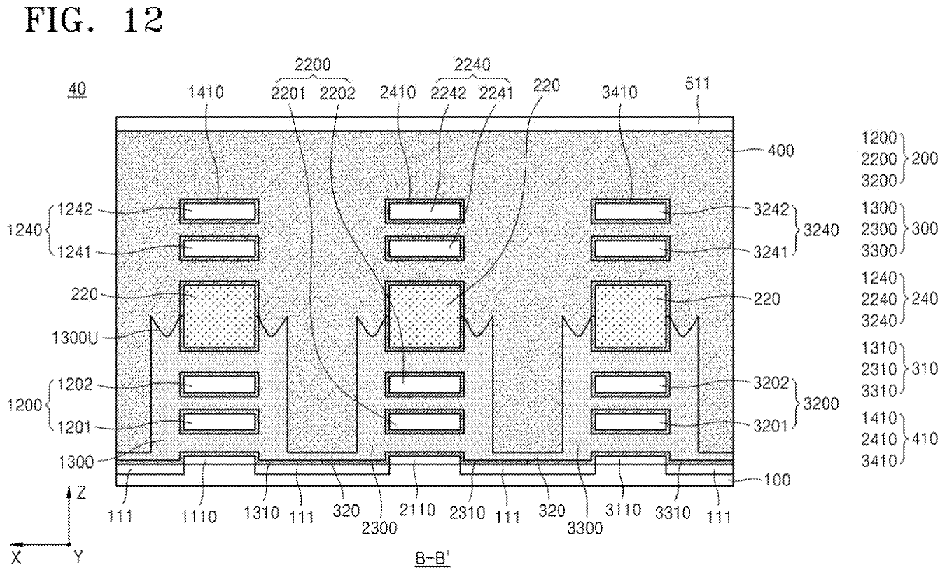

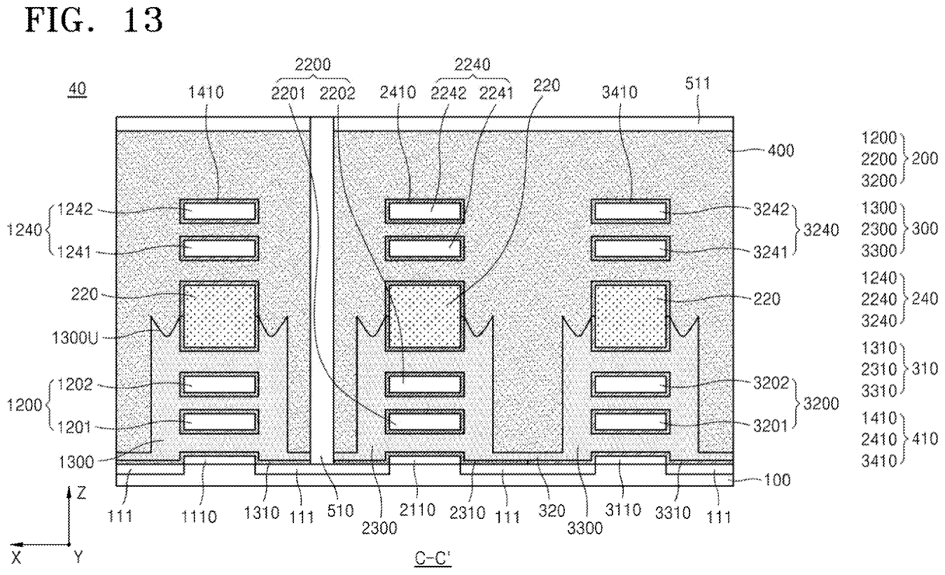

FIG. 10 is a plan view showing a layout of a stacked integrated circuit device. FIG. 11 is a cross-sectional view showing a stacked integrated circuit device taken along a line A-A′ of FIG. 10. FIG. 12 is a cross-sectional view showing a stacked integrated circuit device taken along a line B-B′ of FIG. 10. FIG. 13 is a cross-sectional view showing a stacked integrated circuit device taken along a line C-C′ of FIG. 10.

Referring to FIGS. 10 to 13, the stacked integrated circuit device 40 may include the substrate 100, the lower active region 200, the lower gate pattern 300, the lower dielectric layer 310, the intermediate insulating layer 220, the upper active region 240, the upper gate pattern 400, the upper dielectric layer 410, the lower source/drain region 120, and the upper source/drain region 140.

Hereinafter, details of the stacked integrated circuit device 40 of FIG. 10, which overlap the stacked integrated circuit device 10 of FIG. 1 are omitted, and differences will be described. A lower insulating layer 110 and the lower oxide layer 111 may be on the substrate 100. The lower insulating layer 110 may be surrounded by the lower oxide layer 111.

The lower active region 200 may be above the substrate 100. The lower active region 200 may be on the lower insulating layer 110. The lower insulating layer 110 may include a first lower insulating layer 1110, a second lower insulating layer 2110, and a third lower insulating layer 3110, and different lower active regions 200 may be located on the lower insulating layers 110.

The stacked integrated circuit device 40 may include a plurality of the lower active regions 200. The plurality of lower active regions 200 may be spaced apart from each other on the substrate 100. The plurality of lower active regions 200 may be located on the substrate 100 while being spaced apart from each other in the X-axis direction and/or the Y-axis direction.

The stacked integrated circuit device 40 may include a plurality of the upper gate patterns 400 extending in the X-axis direction. The plurality of upper gate patterns 400 may be spaced apart from each other in the Y-axis direction. Hereinafter, a plurality of the lower active regions 200 located in the upper gate pattern 400 extending in the X-axis direction will be described.

In an implementation, the lower active region 200 may include a first lower active region 1200 to a third lower active region 3200. The first lower active region 1200 to the third lower active region 3200 may be spaced apart from each other. The first lower active region 1200, the second lower active region 2200, and the third lower active region 3200 may be spaced apart from each other in the X-axis direction. In other words, the first lower active region 1200 to the third lower active region 3200 may be located on the substrate 100 while being spaced apart from each other in a horizontal direction.

According to some embodiments, the first lower active region 1200 to the third lower active region 3200 may be the lower active region 200 of FIG. 3, 200a of FIG. 7, or 200b of FIG. 8 described above. In an implementation, the first lower active region 1200 may include a first lower nano-sheet 1201 and a second lower nano-sheet 1202, the second lower active region 2200 may include a first lower nano-sheet 2201 and a second lower nano-sheet 2202, and the third lower active region 3200 may include a first lower nano-sheet 3201 and a second lower nano-sheet 3202.

The intermediate insulating layer 220 may be located on the lower active region 200. The intermediate insulating layer 220 may include a first intermediate insulating layer to a third intermediate insulating layer. The first intermediate insulating layer may be located on the first lower active region 1200, the second intermediate insulating layer may be located on the second lower active region 2200, and the third intermediate insulating layer may be located on the third lower active region 3200. In other words, the intermediate insulating layer 220 may be located on each of the plurality of lower active regions 200.

The upper active region 240 may be located on the intermediate insulating layer 220. In other words, the upper active region 240 may be spaced apart from the lower active region 200 with the intermediate insulating layer 220 therebetween. The intermediate insulating layer 220 may insulate the upper active region 240 and the lower active region 200 from each other.

According to some embodiments, the upper active region 240 may include a first upper active region 1240 to a third upper active region 3240. The first upper active region 1240 may be on the first intermediate insulating layer, the second upper active region 2240 may be on the second intermediate insulating layer, and the third upper active region 3240 may be on the third intermediate insulating layer.

The lower gate pattern 300 may surround the lower active region 200. The lower gate pattern 300 may include a first lower gate 1300 to a third lower gate 3300. The first lower gate 1300 may surround the first lower active region 1200, the second lower gate 2300 may surround the second lower active region 2200, and the third lower gate 3300 may surround the third lower active region 3200.

According to some embodiments, the first lower gate 1300 to the third lower gate 3300 may have a same work function. In other words, the first lower gate 1300 to the third lower gate 3300 may be simultaneously formed and may include a same material. Work functions of the first lower gate 1300 to the third lower gate 3300 may be different from each other.

According to some embodiments, the lower gate pattern 300 may further include a protruding portion 320. The protruding portion 320 may extend from a side wall of one lower gate to a side wall of an adjacent lower gate. In other words, the protruding portion 320 included in one lower gate may electrically connect adjacent lower gates.

The protruding portion 320 may be on the substrate 100. The protruding portion 320 may be located in spaces between the first to third lower gates 1300 to 3300, on the substrate 100. In other words, the protruding portion 320 may be located between the first to third lower gates 1300 to 3300, which are spaced apart from each other, to electrically connect the first to third lower gates 1300 to 3300.

The protruding portion 320 of the first lower gate 1300 may connect the first lower gate 1300 and the second lower gate 2300 to each other. The protruding portion 320 may be at least a portion of the side wall of the first lower gate 1300, the side wall facing the second lower gate 2300, protruding towards the second lower gate 2300 while in contact with the lower oxide layer 111.

In addition, the protruding portion 320 of the second lower gate 2300 may connect the second lower gate 2300 and the third lower gate 3300 to each other. The protruding portion 320 may be a portion remaining without being etched and may be conformally formed on the substrate 100, during a process of forming the lower gate pattern 300.

The protruding portion 320 may electrically connect the first to third lower gates 1300 to 3300 to each other. In an implementation, the protruding portion 320 may be on a side wall of each of the first to third lower gates 1300 to 3300 to electrically connect the first to third lower gates 1300 to 3300 to each other.

According to some embodiments, the lower gate pattern 300 may have an upper surface 1300U having curvature. The upper surfaces 1300U of the first to third lower gates 1300 to 3300 may have curvature. In other words, the upper surface 1300U of the lower gate pattern 300 near the lower active region 200 may have curvature.

The upper surface 1300U of the lower gate pattern 300 near the lower active region 200 and intermediate insulating layer 220 may have a downward convex shape. In addition, the upper surface 1300U of the lower gate pattern 300 near the lower active region 200 and intermediate insulating layer 220 may have curvature such that a thickness (a length in the Z-axis direction) decreases away from the intermediate insulating layer 220.

The upper gate pattern 400 may surround the upper active region 240 and cover the lower gate pattern 300. The upper gate pattern 400 may surround the first to third upper active regions 1240 to 3240 and fill spaces between the upper active regions 240. The upper gate pattern 400 may cover the lower gate pattern 300 and fill a space between the lower gate patterns 300.

According to some embodiments, the lower gate pattern 300 and the upper gate pattern 400 may be located in spaces between the first to third lower active regions 1200 to 3200 in the X-axis direction. In an implementation, the first lower active region 1200 and the second lower active region 2200 may be spaced apart from each other with the lower gate pattern 300 and the upper gate pattern 400 therebetween. In other words, the upper gate pattern 400 may surround side walls of the first to third lower gates 1300 to 3300 of the lower gate pattern 300.

According to some embodiments, the upper gate pattern 400 may be located in spaces between the first to third upper active regions 1240 to 3240. In an implementation, the first upper active region 1240 may be spaced apart from the second upper active region 2240 with the upper gate pattern 400 therebetween.

Among upper surfaces of the lower gate pattern 300, the upper surface 1300U near the intermediate insulating layer 220 may be located lower than a lower surface of the upper active region 240. The upper surface 1300U of the lower gate pattern 300 adjacent to the intermediate insulating layer 220 may be located lower than the upper surface 220U of the intermediate insulating layer 220.

A highest point of the upper surface 1300U of the lower gate pattern 300 adjacent to the intermediate insulating layer 220 may be located higher than the lower active region 200. In other words, the highest point of the upper surface 1300U of the lower gate pattern 300 adjacent to the intermediate insulating layer 220 may be located lower than the upper active region 240 and higher than the lower active region 200.

In an implementation, the lower gate pattern 300 may be in contact with a portion of the intermediate insulating layer 220 and the upper gate pattern 400 may be in contact with a remaining portion of the intermediate insulating layer 220. In other words, the upper gate pattern 400 may cover the lower gate pattern 300, and thus a portion of the intermediate insulating layer 220, which may not be in contact with the lower gate pattern 300, may be in contact with the upper gate pattern 400.

The lower dielectric layer 310 may be between the lower active region 200 and the lower gate pattern 300. A first lower dielectric layer 1310 may be between the first lower active region 1200 and the first lower gate 1300, a second lower dielectric layer 2310 may be between the second lower active region 2200 and the second lower gate 2300, and a third lower dielectric layer 3310 may be between the third lower active region 3200 and the third lower gate 3300.

The upper dielectric layer 410 may be between the upper active region 240 and the upper gate pattern 400. A first upper dielectric layer 1410 may be between the first upper active region 1240 and the upper gate pattern 400, a second upper dielectric layer 2410 may be between the second upper active region 2240 and the upper gate pattern 400, and a third upper dielectric layer 3410 may be between the third upper active region 3240 and the upper gate pattern 400.

Referring to FIG. 11, at least one lower dielectric layer from among a first column lower dielectric layer 310a, a second column lower dielectric layer 310b, and a third column lower dielectric layer 310c, which are arranged in parallel to the Y-axis direction and located in different lower gate patterns 300 spaced apart from each other in the Y-axis direction, may have a different dielectric constant from another lower dielectric layer. The first to third column lower dielectric layers 310a to 310c may have different dielectric constants.

At least one upper dielectric layer from among a first column upper dielectric layer 410a, a second column upper dielectric layer 410b, and a third column upper dielectric layer 410c, which are arranged in parallel to the Y-axis direction and located in different upper gate patterns 400 spaced apart from each other in the Y-axis direction, may have different dielectric constant from another upper dielectric layer. The first to third column upper dielectric layers 410a to 410c may have different dielectric constants.

Referring to FIG. 12, the first lower dielectric layer 1310, the second lower dielectric layer 2310, and the third lower dielectric layer 3310, which are located in one lower gate pattern 300 extending in the X-axis direction, may have different dielectric constants. The dielectric constants of the first to third lower dielectric layers 1310 to 3310 may have different dielectric constants, and thus the lower gate pattern 300 may have various threshold voltages. In FIG. 12, three lower dielectric layers 310 having different dielectric constants are illustrated, and the number of lower dielectric layers 310 having different dielectric constants may be 2, 4, or greater.

The first upper dielectric layer 1410, the second upper dielectric layer 2410, and the third upper dielectric layer 3410, which are located in one upper gate pattern 400 extending in the X-axis direction may have different dielectric constants. The dielectric constants of the first to third upper dielectric layers 1410 to 3410 may have different dielectric constants, and thus the upper gate pattern 400 may have various threshold voltages. In FIG. 12, three upper dielectric layers 410 having different dielectric constants are illustrated, and the number of upper dielectric layers 410 having different dielectric constants may be 2, 4, or greater.

Referring to FIG. 13, the stacked integrated circuit device 40 may include a device isolation layer 510. The device isolation layer 510 may be located between the lower active region 200 and the upper active region 240. The device isolation layer 510 may be in contact with the upper gate pattern 400 and/or the lower gate pattern 300, on both sides.

The device isolation layer 510 may extend in the Y-axis direction to cross the upper gate pattern 400 and lower gate pattern 300, which extend in the X-axis direction, such that the upper gate pattern 400 may be isolated based on the device isolation layer 510. The upper gate patterns 400 isolated by the device isolation layer 510 may not be electrically connected to each other by the device isolation layer 510. If the device isolation layer 510 is extended from an upper surface of the capping layer 511 to the substrate 100, the lower gate pattern 300 may also be isolated by the device isolation layer 510. According to some embodiments, the device isolation layer 510 may include SiN, SiO, SiCN, SiBN, SiON, SiOCN, SiBCN, or SiOC.

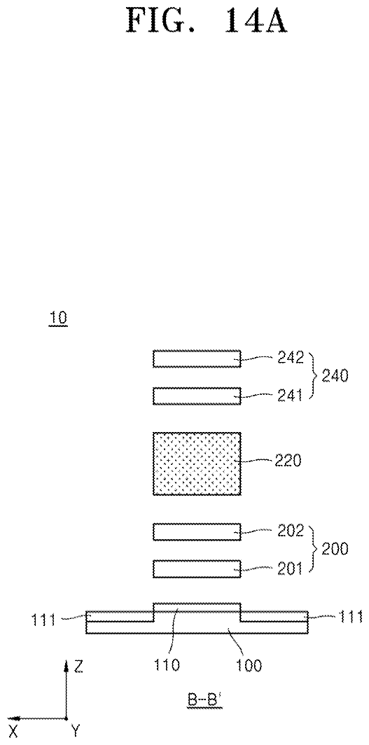

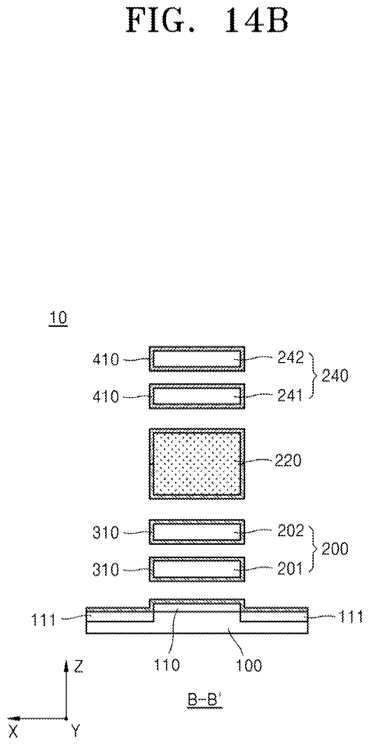

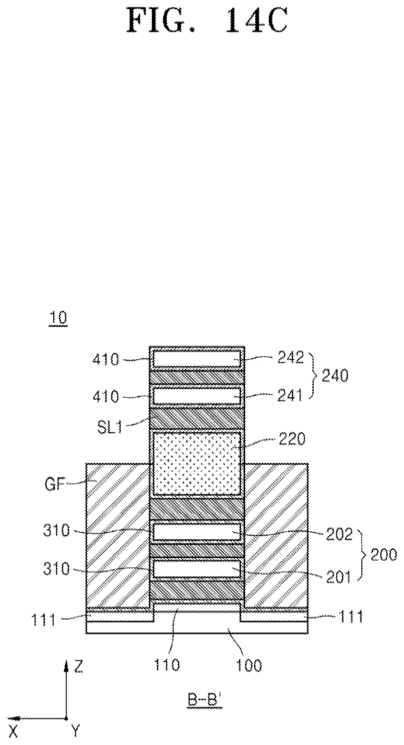

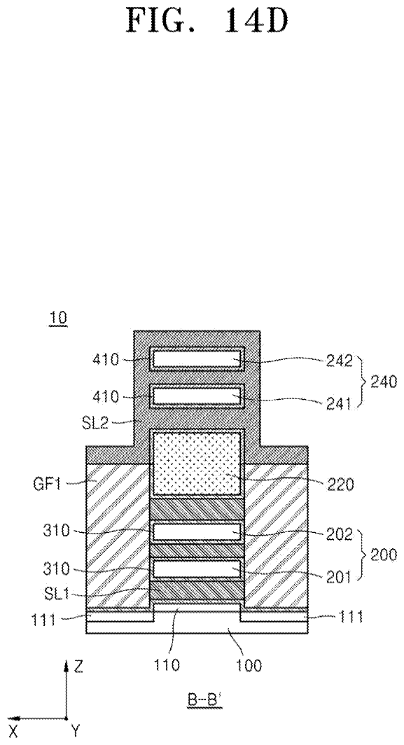

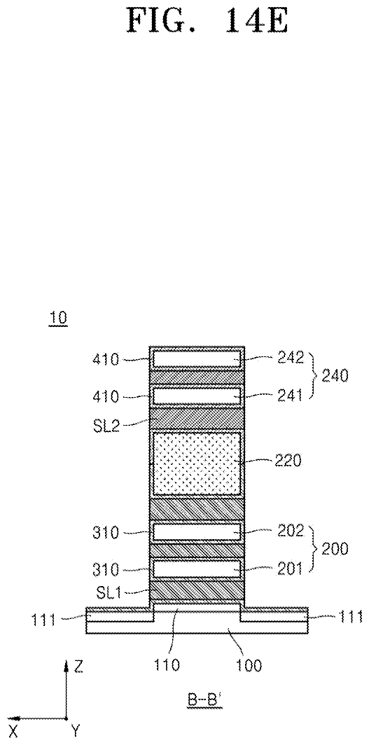

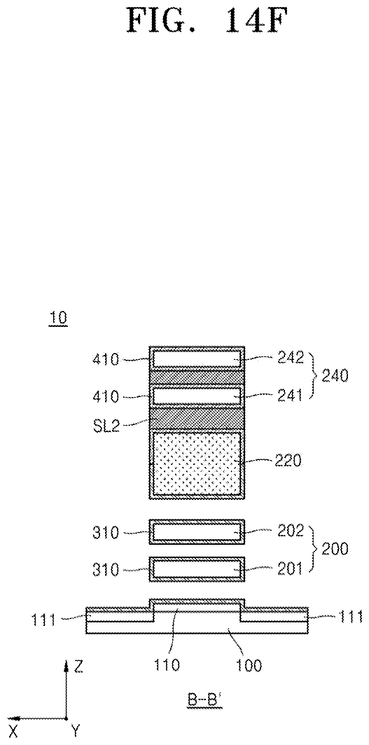

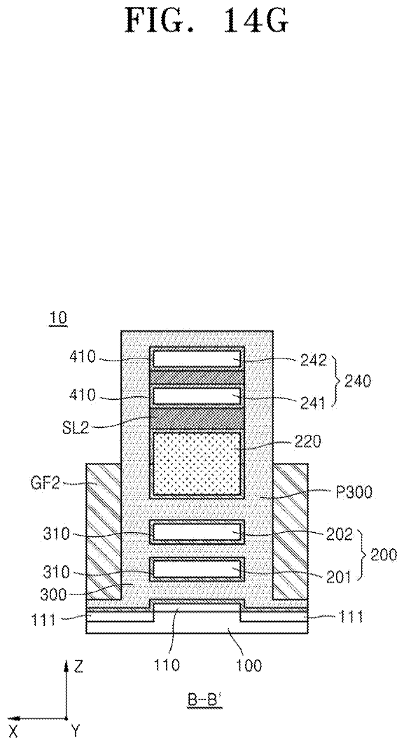

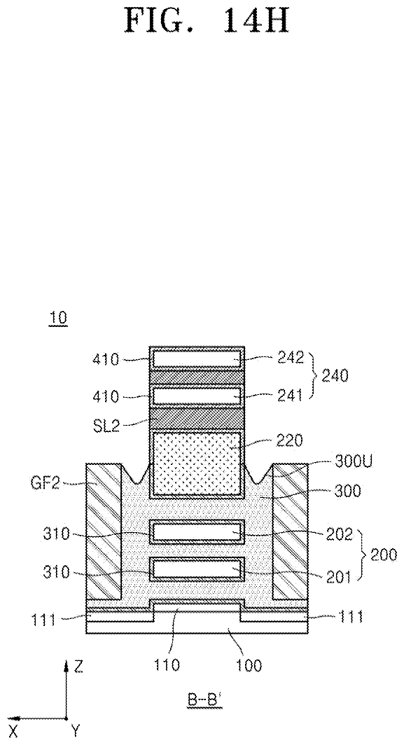

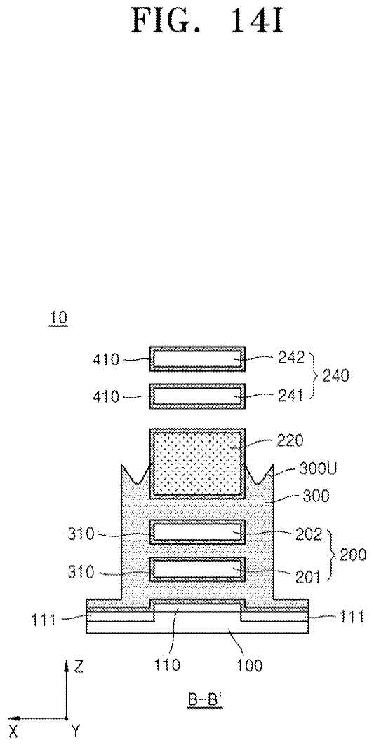

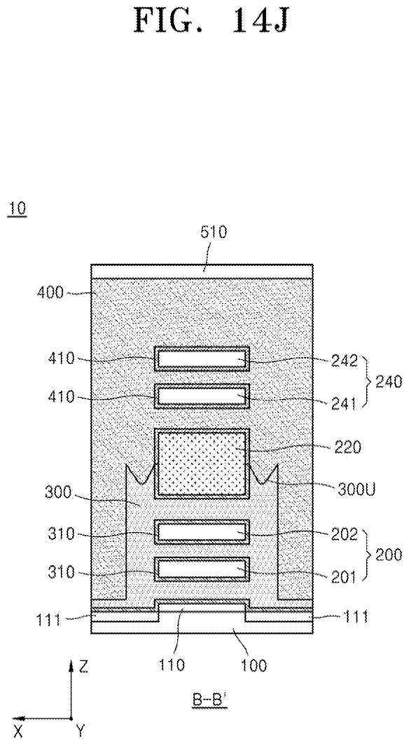

FIGS. 14A to 14J are cross-sectional views showing, in a process sequence, a method of manufacturing a stacked integrated circuit device. FIGS. 14A to 14J are cross-sectional views taken along the line B-B′ of FIG. 1.

Hereinafter, an example in which the lower active region 200 and the upper active region 240 include nano-sheets is described with reference to FIGS. 14A to 14J, and the lower active region 200 and the upper active region 240 may include a fin FET structure or nano-wires.

Referring to FIG. 14A, the lower active region 200, the intermediate insulating layer 220, and the upper active region 240 may be on the substrate 100 where the lower insulating layer 110 and the lower oxide layer 111 are formed.

The substrate 100 may be a wafer including Si. Alternatively, the substrate 100 may be a wafer including a semiconductor element such as Ge, or including a compound semiconductor such as SiC, GaAs, InAs, or InP. The substrate 100 may have a silicon-on-insulator (SOI) structure. The lower insulating layer 110 and the lower oxide layer 111 may be formed on the substrate 100 through a chemical vapor deposition method.

The lower active region 200, the intermediate insulating layer 220, and the upper active region 240 may be stacked on the lower insulating layer 110. According to some embodiments, the lower active region 200, the intermediate insulating layer 220, and the upper active region 240 are stacked by alternately stacking, on the substrate 100, a plurality of nano-sheet semiconductor layers and a plurality of sacrificial layers. Then, through an etching process, the plurality of nano-sheet semiconductor layers and the plurality of sacrificial layers may have certain lengths (lengths in the X-axis direction). Here, an insulating layer that becomes the intermediate insulating layer 220 may be located between the plurality of nano-sheet semiconductor layers.

Next, a dummy gate may be formed after etching the plurality of nano-sheet semiconductor layers and the plurality of sacrificial layers in a length direction, so as to protect the plurality of nano-sheet semiconductor layers and the plurality of sacrificial layers while forming the lower source/drain region 120 of FIG. 2 and the upper source/drain region 140 of FIG. 2.

Then, a recess groove may be on both sides of the plurality of nano-sheet semiconductor layers in the Y-axis direction, and the lower source/drain region 120 of FIG. 2 may be formed through epitaxial growth. The lower source/drain region 120 of FIG. 2 may be formed on both sides of the lower active region 200 through the epitaxial growth.

Next, after the lower source/drain region 120 of FIG. 2 is formed, the first insulating layer 221 of FIG. 2 may be on an upper surface thereof. The first insulating layer 221 of FIG. 2 may be located on both sides of the intermediate insulating layer 220. The upper source/drain region 140 of FIG. 2 may be on the first insulating layer 221 of FIG. 2 through epitaxial growth.

Then, the dummy gate is removed and the plurality of sacrificial layers are removed, so as to form the plurality of nano-sheets spaced apart from each other in a vertical direction. The plurality of nano-sheets formed as such are defined as the lower active region 200 below the intermediate insulating layer 220 and as the upper active region 240 above the intermediate insulating layer 220, based on the intermediate insulating layer 220.

Referring to FIG. 14B, the lower dielectric layer 310 and the upper dielectric layer 410 are respectively at the lower active region 200 and the upper active region 240.

Then, after depositing the lower dielectric layer 310 on the upper active region 240, the intermediate insulating layer 220, and the lower active region 200, a gap-filling layer may be formed up to the intermediate insulating layer 220 and the lower dielectric layer 310 may be etched, so as to form the lower dielectric layer 310 in the lower active region 200 and at least a portion of the intermediate insulating layer 220.

Next, the upper dielectric layer 410 may be deposited above the gap-filling layer, a remaining portion of the intermediate insulating layer 220, and the upper active region 240. Then, by removing the gap-filling layer, the lower dielectric layer 310 may be formed in the lower active region 200 and the upper dielectric layer 410 may be formed in the upper active region 240. Here, boundaries of the lower dielectric layer 310 and the upper dielectric layer 410 formed at the intermediate insulating layer 220 may vary depending on a height of the gap-filling layer.

After such a process, quality of the upper dielectric layer 410 and lower dielectric layer 310 may be improved through an annealing process. The annealing process may be omitted.

Referring to FIGS. 14C to 14E, a second sacrificial layer SL2 may be formed in a space between the plurality of upper nano-sheets of the upper active region 240, and a first sacrificial layer SL1 may be formed in a space between the plurality of lower nano-sheets of the lower active region 200.

The first sacrificial layer SL1 may be formed in the spaces between the plurality of upper nano-sheets and the plurality of lower nano-sheets, through a deposition process such as atomic layer deposition (ALD). Then, a gap-filling layer GF1 may be on both sides of the lower active region 200, and the first sacrificial layer SL1 above the gap-filling layer GF1 may be etched to remove the first sacrificial layer SL1 formed in the space between the plurality of upper nano-sheets.

Next, the second sacrificial layer SL2 may be deposited through ALD to form the second sacrificial layer SL2 in the space between the plurality of upper nano-sheets and above the gap-filling layer GF1. An etch selectivity of the second sacrificial layer SL2 with respect to the first sacrificial layer SL1 may be great or small. In other words, the second sacrificial layer SL2 may have a different etching speed from the first sacrificial layer SL1.

Then, the gap-filling layer GF1 may be removed such that the first sacrificial layer SL1 may be in the space between the plurality of lower nano-sheets and the second sacrificial layer SL2 is located in the space between the plurality of upper nano-sheets.

Referring to FIG. 14F, the first sacrificial layer SL1 may be etched to remove the first sacrificial layer SL1 located in the space between the plurality of lower nano-sheets. Here, an etch rate of the second sacrificial layer SL2 and an etch rate of the first sacrificial layer SL1 are different from each other, and thus the second sacrificial layer SL2 may remain without being removed.

Referring to FIG. 14G, a preliminary lower gate pattern P300 and a gap-filling layer GF2 may be formed. The preliminary lower gate pattern P300 may be deposited through ALD, and a portion of the preliminary lower gate pattern P300 may be provided in a space between the plurality of lower nano-sheets and a remaining portion of the preliminary lower gate pattern P300 may cover a surface of the upper active region 240 and a surface of the second sacrificial layer SL2. In other words, the preliminary lower gate pattern P300 may entirely surround even an internal empty space of the lower active region 200.

Next, the gap-filling layer GF2 may be filled in both sides of the preliminary lower gate pattern P300 to externally expose a portion of the preliminary lower gate pattern P300 and protect a remaining portion thereof during an etching process. Here, an etch selectivity of the second sacrificial layer SL2 with respect to the preliminary lower gate pattern P300 may be great or small. In other words, the second sacrificial layer SL2 may have a different etching speed from the preliminary lower gate pattern P300.

Referring to FIG. 14H, a portion of the preliminary lower gate pattern P300 may be recessed to form the lower gate pattern 300. The preliminary lower gate pattern P300 may be removed through wet etching or dry etching, so as to expose the upper active region 240, the second sacrificial layer SL2, and a portion of the intermediate insulating layer 220. The preliminary lower gate pattern P300 may be wet-etched to form the lower gate pattern 300.

While forming the lower gate pattern 300, the upper surface 300U of the lower gate pattern 300 may have curvature. In other words, while forming the lower gate pattern 300, an etching speed changes for each region of the preliminary lower gate pattern P300, and thus the upper surface 300U of the lower gate pattern 300 may have curvature.

According to some embodiments, the upper surface 300U of the lower gate pattern 300 may have a downward convex shape or may have a shape adjacent to the substrate 100 away from the intermediate insulating layer 220. However, if the preliminary lower gate pattern P300 is recessed through dry etching, the upper surface 300U of the lower gate pattern 300 may be flat.

Referring to FIGS. 14I to 14J, the upper gate pattern 400 may be formed and the capping layer 511 may be formed. An etching process may be performed to remove the second sacrificial layer SL2 located in the upper active region 240. Here, the lower gate pattern 300 may not be substantially etched due to a high etch selectivity with respect to the second sacrificial layer SL2. In other words, the lower gate pattern 300 may not be removed while removing the second sacrificial layer SL2.

The upper gate pattern 400 may cover the lower gate pattern 300 and surround the upper active region 240 from which the second sacrificial layer SL2 is removed. In other words, the upper gate pattern 400 may fill an empty space in an upper portion of the lower gate pattern 300. Then, the capping layer 511 for protecting the upper gate pattern 400 may be formed.

By way of summation and review, as the degree of integration of integrated circuit devices increases and their sizes decrease, a multilayer structure in which integrated circuit devices are stacked in a vertical direction is required. There is a need to develop a structure for reducing the sizes of integrated circuit devices, for integrated circuit devices having such a multilayer structure.

A stacked integrated circuit device in which designing of a gate pattern is facilitated by individually patterning an upper gate pattern and a lower gate pattern is disclosed. A stacked integrated circuit device in which designing of an upper source/drain region and a lower source/drain region is facilitated.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A stacked integrated circuit device, comprising:
a lower active region;
a lower gate pattern surrounding the lower active region;
a lower dielectric layer between the lower active region and the lower gate pattern;
an intermediate insulating layer on the lower active region;
an upper active region on the intermediate insulating layer;
an upper gate pattern surrounding the upper active region and covering the lower gate pattern; and
an upper dielectric layer between the upper active region and the upper gate pattern,
wherein an upper surface of the lower gate pattern is located lower in a vertical direction than an upper surface of the intermediate insulating layer, and
the lower gate pattern surrounds at least a portion of a side surface of the intermediate insulating layer.

2. The stacked integrated circuit device as claimed in claim 1, wherein a work function of the upper gate pattern and a work function of the lower gate pattern are different from each other.

3. The stacked integrated circuit device as claimed in claim 1, further comprising:
a pair of lower source/drain regions on both sides of the lower gate pattern; and
a pair of upper source/drain regions on both sides of the upper gate pattern,
wherein the lower active region includes surfaces in contact with the pair of lower source/drain regions, and
the upper active region includes surfaces in contact with the pair of upper source/drain regions.

4. The stacked integrated circuit device as claimed in claim 3, wherein a type of a dopant with which the pair of upper source/drain regions are doped and a type of a dopant with which the pair of lower source/drain regions are doped are different from each other.

5. The stacked integrated circuit device as claimed in claim 1, wherein the upper gate pattern is in contact with an upper surface and a side surface of the lower gate pattern and electrically connected to the lower gate pattern.

6. The stacked integrated circuit device as claimed in claim 1, further comprising a gate insulating layer between the lower gate pattern and the upper gate pattern.

7. The stacked integrated circuit device as claimed in claim 6, wherein the gate insulating layer is conformally formed on a surface of the lower gate pattern.

8. The stacked integrated circuit device as claimed in claim 1, wherein the lower gate pattern has an upper surface having a downward convex shape.

9. The stacked integrated circuit device as claimed in claim 8, wherein a difference of height in the upper surface of the lower gate pattern is 1 nm to 10 nm.

10. The stacked integrated circuit device as claimed in claim 1, wherein the lower gate pattern has an upper surface perpendicular to the vertical direction.

11. The stacked integrated circuit device as claimed in claim 1, wherein an upper surface of the lower gate pattern decreases in the vertical direction if spaced apart from the intermediate insulating layer in a horizontal direction.

12. The stacked integrated circuit device as claimed in claim 1, wherein a lowest point of an upper surface of the lower gate pattern is located higher in the vertical direction than an upper surface of the lower active region.

13. The stacked integrated circuit device as claimed in claim 1, wherein a thickness from an upper surface to a lower surface of the intermediate insulating layer is about 20 nm to about 50 nm.

14. The stacked integrated circuit device as claimed in claim 1, wherein:
a portion of the intermediate insulating layer is in contact with the lower gate pattern, and
a remaining portion of the intermediate insulating layer is in contact with the upper gate pattern.

15. The stacked integrated circuit device as claimed in claim 14, wherein:
a portion of a side surface of the intermediate insulating layer is covered by the upper dielectric layer, and
a remaining portion of the side surface of the intermediate insulating layer is covered by the lower dielectric layer.

16. A stacked integrated circuit device, comprising:
a lower active region including a first lower active region and a second lower active region spaced apart in a horizontal direction from the first lower active region;
a lower gate pattern including a first lower gate and a second lower gate, the first lower gate surrounding the first lower active region, and the second lower gate surrounding the second lower active region;
a first lower dielectric layer between the first lower active region and the first lower gate;
a second lower dielectric layer between the second lower active region and the second lower gate;
an intermediate insulating layer including a first intermediate insulating layer and a second intermediate insulating layer, the first intermediate insulating layer on the first lower active region, and the second intermediate insulating layer on the second lower active region;
an upper active region including a first upper active region and a second upper active region, the first upper active region on the first intermediate insulating layer, and the second upper active region on the second intermediate insulating layer;
an upper gate pattern surrounding the upper active region and covering the lower gate pattern;
a first upper dielectric layer between the first upper active region and the upper gate pattern; and
a second upper dielectric layer between the second upper active region and the upper gate pattern,
wherein the lower gate pattern surrounds a portion of a side surface of the intermediate insulating layer, and
the upper gate pattern surrounds a remaining portion the surface side of the intermediate insulating layer.

17. The stacked integrated circuit device as claimed in claim 16, wherein:
the first lower gate includes a protruding portion extending from one side of the first lower gate to one side of the second lower gate, and
the protruding portion electrically connects the first lower gate and the second lower gate to each other.

18. The stacked integrated circuit device as claimed in claim 16, wherein:
the lower gate pattern and the upper gate pattern are located between the first lower active region and the second lower active region, and
the upper gate pattern is located between the first upper active region and the second upper active region.

19. The stacked integrated circuit device as claimed in claim 16, wherein the first lower gate and the second lower gate each have an upper surface having curvature.

20. A stacked integrated circuit device, comprising:
a lower active region;
a lower gate pattern surrounding the lower active region and including a protruding portion;
a lower dielectric layer between the lower active region and the lower gate pattern;
an intermediate insulating layer on the lower active region;
an upper active region on the intermediate insulating layer;
an upper gate pattern surrounding the upper active region, covering the lower gate pattern, and electrically connected to the lower gate pattern; and
an upper dielectric layer between the upper active region and the upper gate pattern,
wherein a threshold voltage of the upper gate pattern and a threshold voltage of the lower gate pattern are different from each other,
an upper surface of the lower gate pattern is located lower in a vertical direction than an upper surface of the intermediate insulating layer, and has a downward convex shape,
the lower gate pattern surrounding a portion of a side surface of the intermediate insulating layer, and
the upper gate pattern surrounding a remaining portion of the side surface of the intermediate insulating layer.
